(19) United States
(12) Patent Application Publication
(10) Pub. No.: US 2012/0080984 A1
(43) Pub. Date: Apr. 5, 2012

(54) ASSEMBLABLE SERVER CABINET

(75) Inventor: Billy D. Watts, Corrales, NM (US)

(73) Assignee: DATA CENTER TRANSITIONS, INC., Corrales, NM (US)

(21) Appl. No.: 13/250,531

(22) Filed: Sep. 30, 2011

Related U.S. Application Data
(60) Provisional application No. 61/388,557, filed on Sep. 30, 2010.

(51) Int. Cl. H05K 5/02; B66F 5/00; A47B 96/06

(52) U.S. Cl. 312/223.2; 254/2 R

(57) ABSTRACT

A server cabinet which can be shipped in a disassembled condition and assembled by a user, thus reducing shipping costs and shipping damages. Optionally, frame components can be formed from just a few extrusions which can be connected with a bracket.

### CROSS-REFERENCE TO RELATED APPLICATIONS

This application claims priority to and the benefit of the filing of U.S. Provisional Patent Application Ser. No. 61/388,557, entitled “Server Cabinet”, filed on Sep. 30, 2010, and the specification thereof is incorporated herein by reference.

### BACKGROUND OF THE INVENTION

1. Field of the Invention (Technical Field)

Embodiments of the present invention relate to a rack cabinet. Particularly, embodiments of the present invention relate to a server cabinet that can be shipped as a plurality of parts and assembled by the user.

2. Description of Related Art

Over the years, the need to securely mount assemblies of electronic components has led to the development of rack mounting systems. Computers, and particularly the explosion of the Internet, have led to the advent of modern-day rack cabinets—most notably server cabinets. Server cabinets range from relatively small enclosures to very large enclosures—large enough for a person to walk into. The design and construction of such large enclosures are often plagued with problems, including the ability of the structures to adequately support the thousands of pounds of electronics equipment that are often bolted into their racks, as well as the immense amounts of heat generated from the thousands of watts that are often fed into and thus dissipated within their confines.

Large cabinets are typically made structurally strong by welding the various frame components together. Because such fully welded structures cannot be disassembled for shipping, these large cabinets, which can often exceed 7 feet in height must be shipped in a fully, or almost fully assembled state. Thus, one cabinet is all that can fit onto a shipping pallet and the space occupied by the assembled server cabinet during shipping is exceedingly large. To top it off, the tall cabinets are typically shipped standing up since their sides could easily become bent if shipped lying on a side. Therefore, the tall cabinets are top-heavy and can easily fall during shipping, thus resulting in a large percentage of units being damaged during shipping, as well as a very large shipping bill for each cabinet. These configurations are susceptible to further shipping damage from the shifting loads of other items shipped in the same shipment as the shipment may not be a full truckload.

A few cabinets have been developed which can be shipped in a disassembled and stacked state, thereby greatly reducing the cost of shipping and greatly reducing the percentage of units damaged during shipping. The problems with these known cabinets, however, is that their frames are typically constructed from several different frame members and are not simply a couple different types of extrusions which are simply cut to form all of the different frame members needed. Accordingly, because several different types of frame members must be created for each cabinet, the cost of design and manufacture of the known cabinets is much more than it is for the instant invention.

Because known cabinets, which can be disassembled, typically rely on inserts which are inserted into tubing frame members, in order to secure the frame members together, such inserts are thus necessarily small and therefore insubstantial. Because the resulting constructed frame is no stronger than its weakest point, the constructed frame is not capable of supporting substantial loads and is not as strong as a constructed cabinet which does not rely on flimsy inserts.

Further still, such known systems do not provide a quick and secure quick-lock connection for securing the frame together as is taught in the instant application. The traditional nuts-and-bolts relied on by the known systems are much more difficult to manipulate into position and often require two workers in order to assemble the cabinet. This is because the frame members must be held together, as well as the corner insert, and the openings through the various components for the bolt must simultaneously be aligned and the bolt inserted and the nut held in place while the bolt is turned. Such a challenging task is difficult to perform even when two people work to assemble such a structure. The need for several people to assemble the cabinet instead of just one or two drives the total cost of the assembled cabinet up even further.

In order to adequately control air-flow through the server equipment and server cabinet, panels on the sides, top and bottom of the cabinet are often used to provide barriers to undesired airflow. These panels are often very large and when removable present a risk of injury to feet, toes and fingers. In addition, areas close to these panels are often inaccessible when server equipment is installed in the server cabinet and these areas thus become pathways for air to flow, thereby by-passing the cooling intakes for the server equipment.

There is thus a present need for a rack cabinet which can be assembled by a single person after shipping to a desired location, which cabinet, when so constructed, is capable of supporting significant amounts of weight.

### BRIEF SUMMARY OF EMBODIMENTS OF THE PRESENT INVENTION

An embodiment of the present invention relates to a server cabinet which includes extruded frame members that have a plurality of groves within which heads of fasteners are slidably disposable; and corner brackets having holes through which the head of a fastener can pass, at least two of the holes at least substantially aligning with at least one of the plurality of groves of the frame members when at least an end portion of at least two extruded members are positioned onto the corner brackets.

Optionally, the extruded frame members can include a plurality of members that are formed from at least one extruded shape. In one embodiment, at least some of the plurality holes in the corner brackets have a non-circular shape. Optionally, at least some of the plurality of holes of the corner brackets can include a shape through which a head of a fastener can pass but through which the fastener cannot be removed after it is partially rotated.

The server cabinet can include at least one T-shaped bracket. Optionally, at least some of the extruded members can be formed from an aluminum material. A plurality of lift points can also be provided, which can optionally include a self-aligning portion. The self-aligning portion can include an inverted V-shape. In one embodiment, the lift points can be bolted into place through at least one of the frame members and one of the corner brackets.

An embodiment of the present invention also relates to a server cabinet assembly that includes a plurality of frame members, at least one corner bracket, a plurality of fasteners with which a user can assemble the cabinet; and the frame members and the corner bracket are not disposed in a slidable relationship with one another without fasteners disposed through the corner bracket.

In some embodiments, the frame members do not include elongated hollow structures, nor are they tubular, nor do they include a hollow interior. The corner brackets do not project into an opening in the frame members.

An embodiment of the present invention relates to a lifting jack that includes a plurality of wheels, a plurality of lifting blocks that are engagable with lift points on an item to be lifted, and a jack moving handle for moving the jack and a load disposed on it. The lifting jack can include an input/output port for communicating with another lifting jack; one or more stop blocks; a lifting frame and/or a lifting assembly. Optionally, more than one lifting jack can be provided such that they are or can be communicably coupled in a master/slave relationship such that when one jack is manipulated the other jack is also manipulated.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. In the drawings:

FIG. 1 is a perspective view drawing illustrating a cabinet according to an embodiment of the present invention wherein an opening is provided on the front of the cabinet at an upper end thereof for passage of cables and an opening is provided at the top of the unit for airflow;

FIGS. 2A-D respectively illustrate perspective view drawings of a single server cabinet, an assembly (module frame) of server cabinets, and components thereof according to an embodiment of the present invention;

FIG. 3 is a perspective view drawing illustrating an embodiment of the present invention wherein the side panels are removed such that the internal frame construction is visible;

FIG. 4 is a side view drawing illustrating an embodiment of the present invention;

FIGS. 5A and B are perspective view drawings illustrating alternative embodiments of a lower inside corner of the frame of the present invention;

FIGS. 6A and B are perspective view drawings which illustrate a corner bracket according to an embodiment of the present invention;

FIG. 7 is a perspective view drawing illustrating a fastener according to an embodiment of the present invention;

FIG. 8 is a drawing illustrating a T-bracket according to an embodiment of the present invention;

FIGS. 9A and B are perspective view drawings illustrating an angled elongated frame member according to an embodiment of the present invention;

FIG. 10A-E are drawings which respectively illustrate front, left, bottom, top and an elevated perspective view of a T-shaped elongated frame member according to an embodiment of the present invention, note that the back view is the same as the front view and the right view is the same as the left view;

FIGS. 11 and 12 are perspective view drawings illustrating a flat elongated frame member according to an embodiment of the present invention;

FIG. 13 is a perspective view drawing illustrating a brush attached to an elongated frame member;

FIGS. 14A and B are perspective view drawings which illustrate a lift point with self-aligning members according to embodiments of the present invention;

FIG. 15 is a drawing of a cabinet according to an embodiment of the present invention wherein a cable retention bar is provided;

FIGS. 16 and 17 are drawings illustrating an embodiment of a lifting jack according to an embodiment of the present invention;

FIG. 18 is a drawing which illustrates a plurality of jacks positioned around a cabinet of the present invention such that it may be lifted by the jacks;

FIGS. 19-22 are perspective-view drawings which respectively illustrate various views of a lifting jack according to an embodiment of the present invention;

FIGS. 23A and B are drawings which illustrate an embodiment of the present invention wherein two lifting jacks are positioned to lift a cabinet of the present invention;

FIGS. 24 and 25 are perspective and top views which illustrate three lifting jacks according to an embodiment of the present invention, which are positioned to lift an assembly of jacks of the present invention; and

FIG. 26 is a perspective view drawing which illustrates an adaptor lift plate positioned on a lifting jack according to an embodiment of the present invention.

### DETAILED DESCRIPTION OF THE INVENTION

An embodiment of the present invention relates to an equipment rack cabinet, including but not limited to a server cabinet, which can be easily assembled with fasteners by a user. Particularly, embodiments of the present invention relate to a rack cabinet in which electronics components are secured, including computer components, audio and/or visual components, and the like, which cabinet is shipped in a flattened and at least partially disassembled state and the cabinet is subsequently assembled by a user.

In one embodiment, the present invention relates to a computer hardware cabinet and more particularly a computer-server cabinet.

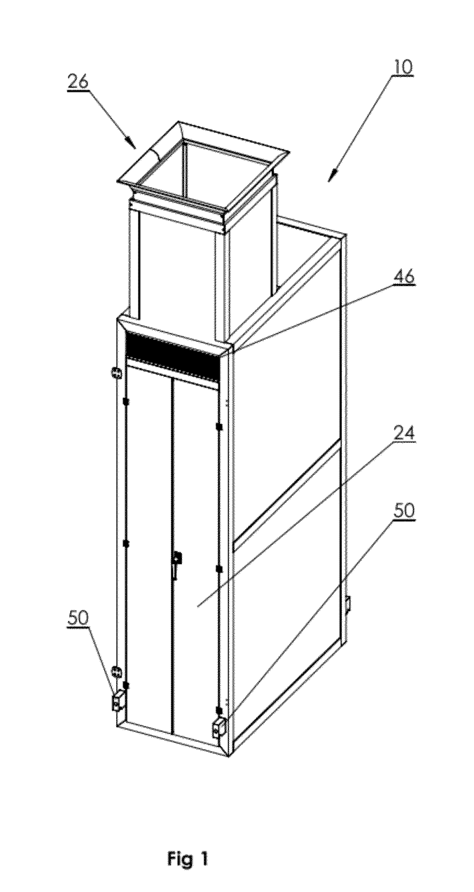

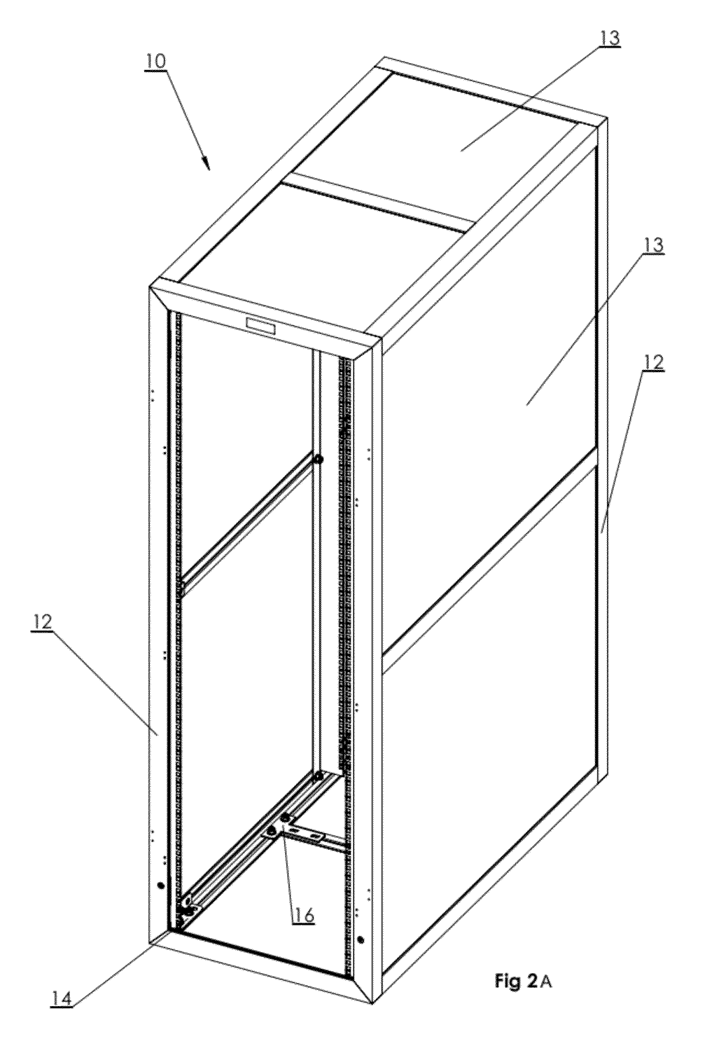

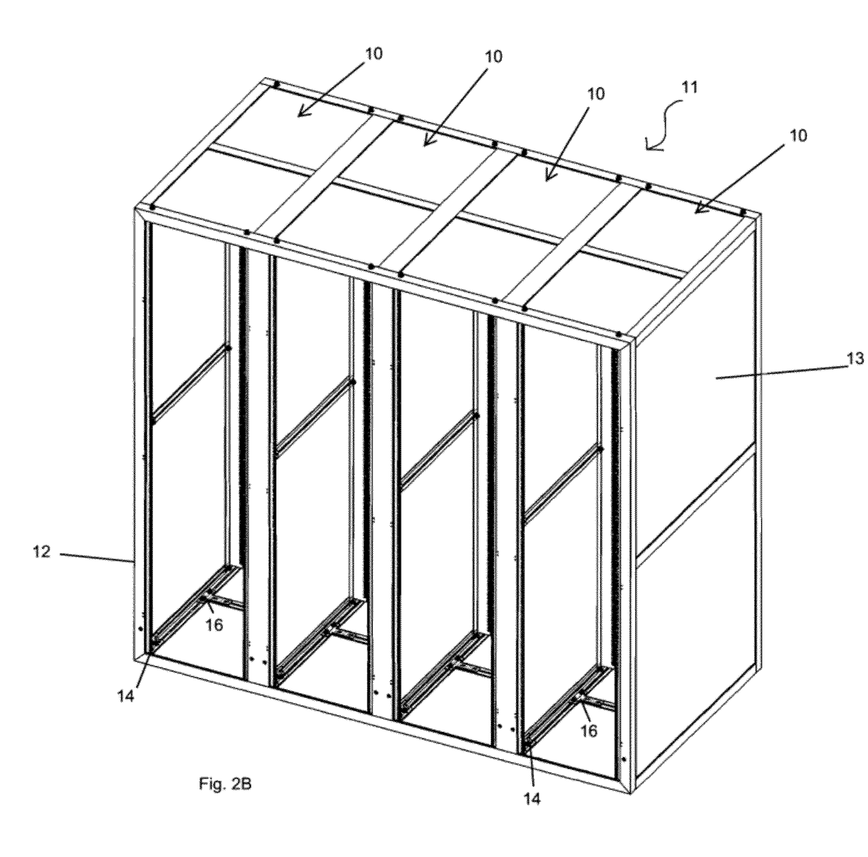

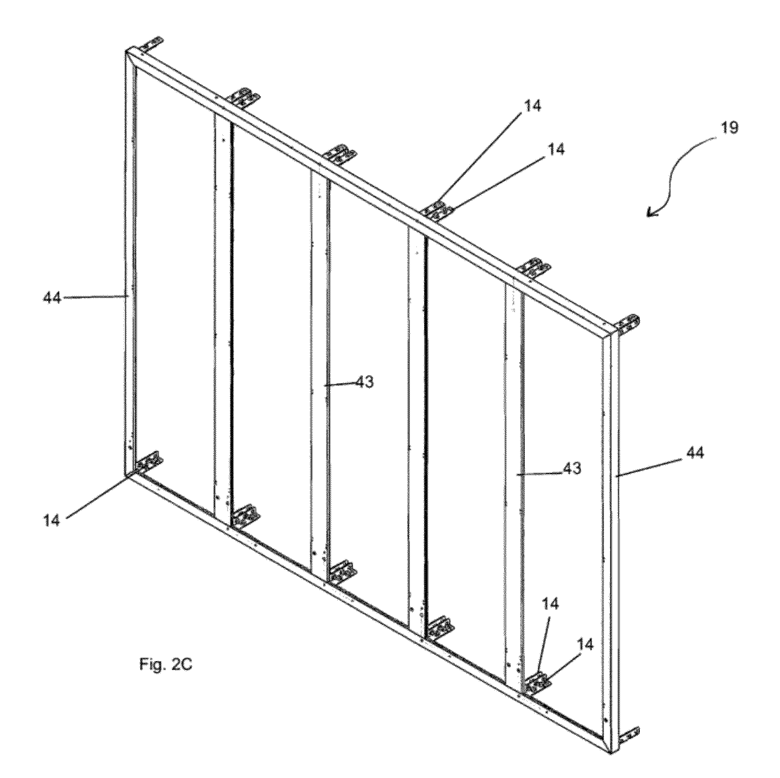

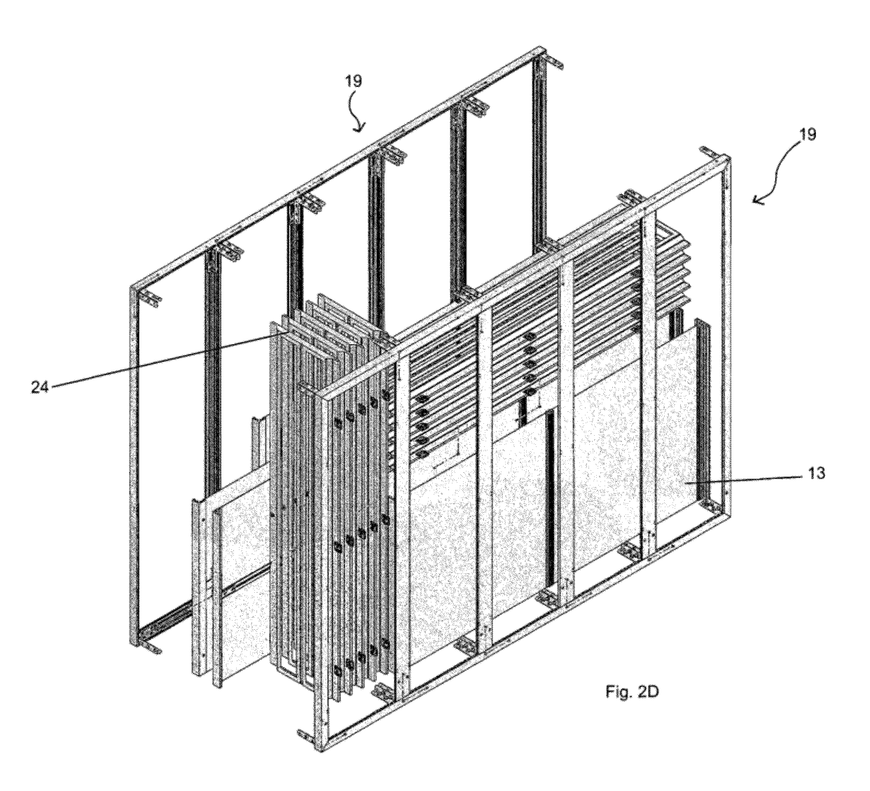

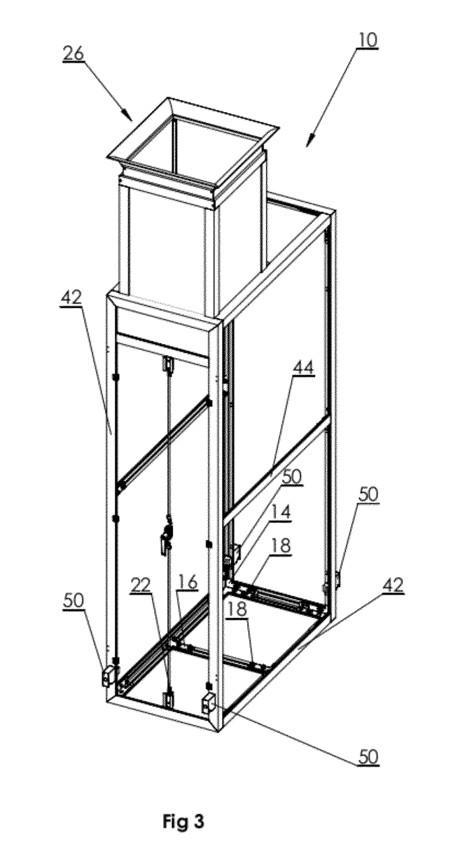

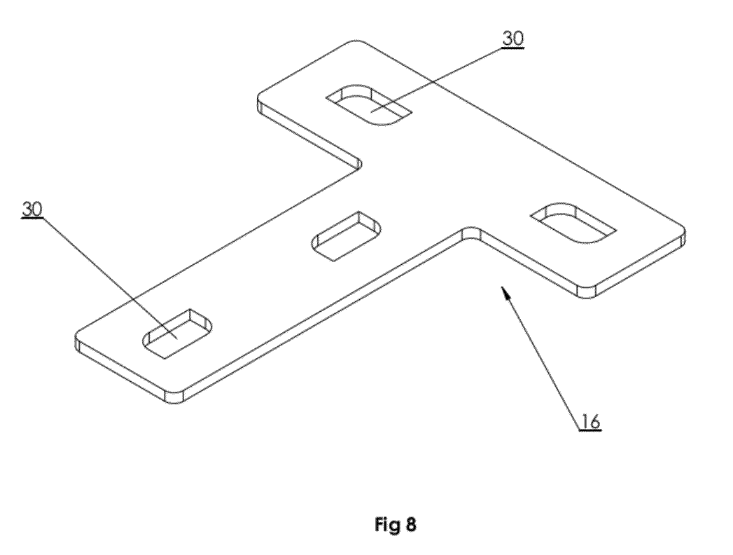

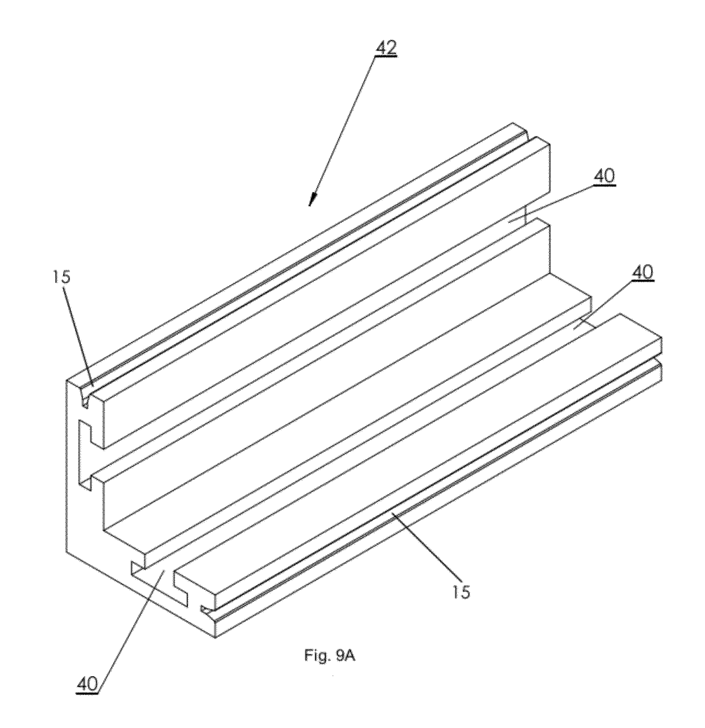

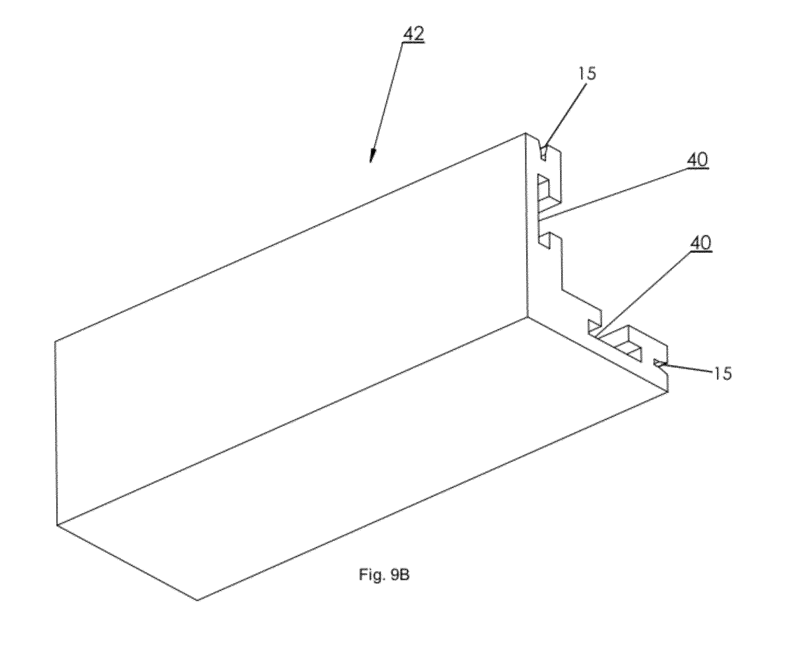

Referring now to FIGS. 1-4, embodiments of the present invention comprise cabinet 10, which is preferably formed from frame 12. Frame 12 comprises a plurality of elongated frame members which are held together with corner bracket 14, T-bracket 16, and one or more fasteners 18. Optionally, front and rear frame components can be bolted and welded together into front and/or rear frame assembly 19 (see FIG. 2C) such that the front and rear portions of the frame are extremely strong yet can be shipped to a user in a flat condition and the user can then connect the front and rear frames together with frame components. Optionally, an entire assembly of cabinets 10 can be shipped in a relatively small space and semi-disassembled state as is illustrated in FIG. 2D. Optionally, handle 20 can be provided and connected to latch 22 such that one or more doors 24 can be provided on cabinet 10. After frame 12 has been assembled, cabinet 10 can be enclosed, at least partially, by providing one or more panels 13. Panels 13 are preferably held in place within frame 12 by disposing them within grooves 15 which are disposed within the frame members (see FIGS. 9-12). Although panels 13 can optionally be loosely held in place, it is preferable that panels 13 are held fast in grooves 15 via an interference fit. Although panels 13 can be constructed from virtually any solid building material that can be formed into sheets, and although plastic, fiberglass, and/or other composite materials can provide desirable results, panels 13 are preferably constructed from a metal material, most preferably steel or aluminum. In one embodiment, panels 13 have a powder coating applied to one or more surfaces thereof. Optionally, cabinet 10 comprises chimney 26, through which heated air can be ducted away from components disposed within cabinet 10. In one embodiment, as best illustrated in FIG. 2B, a plurality of cabinets 10 can be connected together to form a connected assembly of cabinets. Optionally, cabinets 10 can be configured to any desired width to hold any desired width of rack or components that are desired to be disposed therein.

Although the figures illustrate chimney 26 disposed on a top of cabinet 10, chimney 26 can optionally be disposed at various locations while still providing desirable results. Optionally, chimney 26 can be eliminated and the air simply vented from cabinet 10 at one or more openings. In one embodiment, cabinet 10 can have one or more openings provided for air intake. In one embodiment, the air intake can be provided on a bottom of cabinet 10. The cabinet can be set directly upon the raised floor support structure (piers and stringers) without using floor tiles. In one embodiment, the cooling air can enter directly into the cabinet through an open panel in the bottom front of the cabinet. In an alternative embodiment, the bottom panels preferably remain attached to the cabinet, thus blocking air into the bottom of the cabinet while replacing the floor tiles, thereby reducing cost of the flooring support system. As with other large server cabinets, cabinet 10 can be placed on a raised floor and cooled air can be directed up through the bottom of the cabinet, wherein the air is heated by the components operating within cabinet 10. In one embodiment, the heated air can be expelled out of chimney 26 wherein it can enter into a space above a dropped ceiling. An air conditioning return duct is preferably also disposed in the space above the dropped ceiling. Accordingly, the heated air from cabinet 10 is thus collected by the air conditioning unit where it is cooled and before being re-introduced into the raised floor for reuse by cabinet 10. Alternatively, cooled air from an air conditioning unit can optionally be introduced into the room where cabinet 10 is disposed and can enter cabinet 10 at any selected location which is communicable to the air within the room. The air which has been heated by components within cabinet 10 is then preferably ducted through chimney 26 into the space above a dropped ceiling where the heated air is pulled into a return air vent of the air conditioning unit.

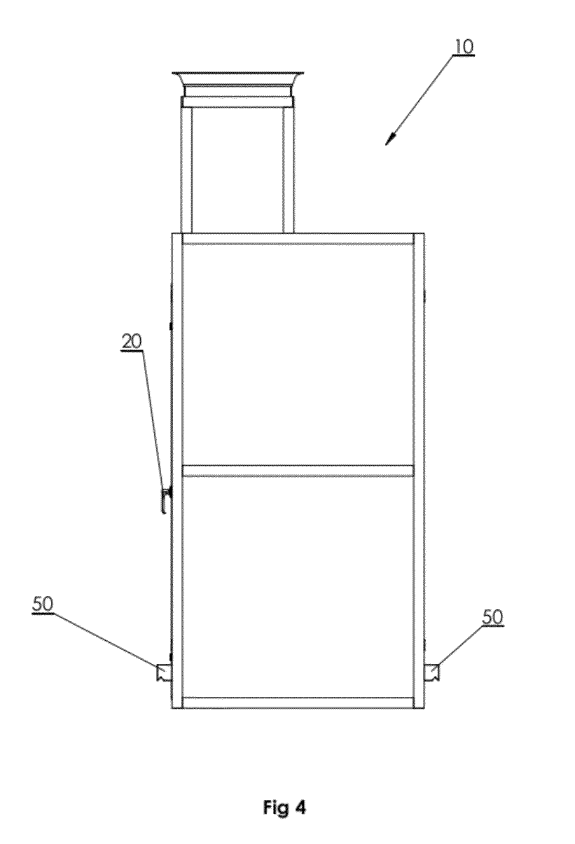

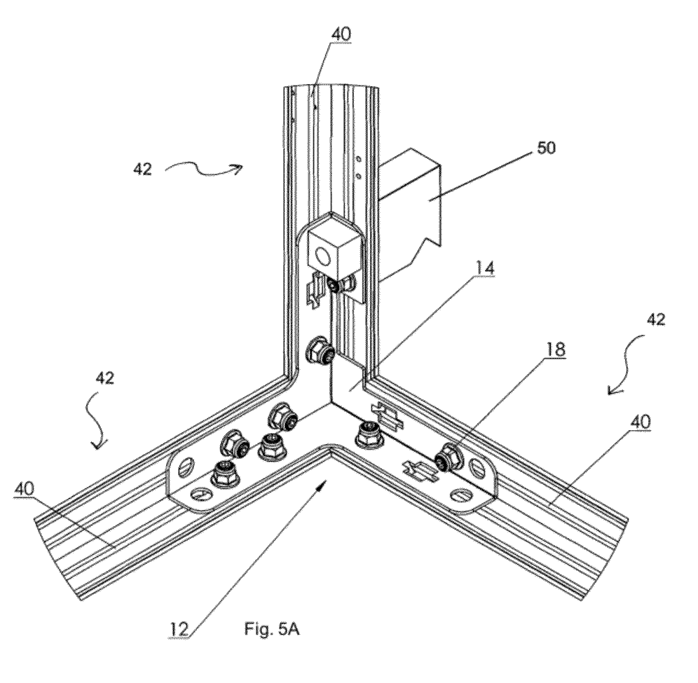

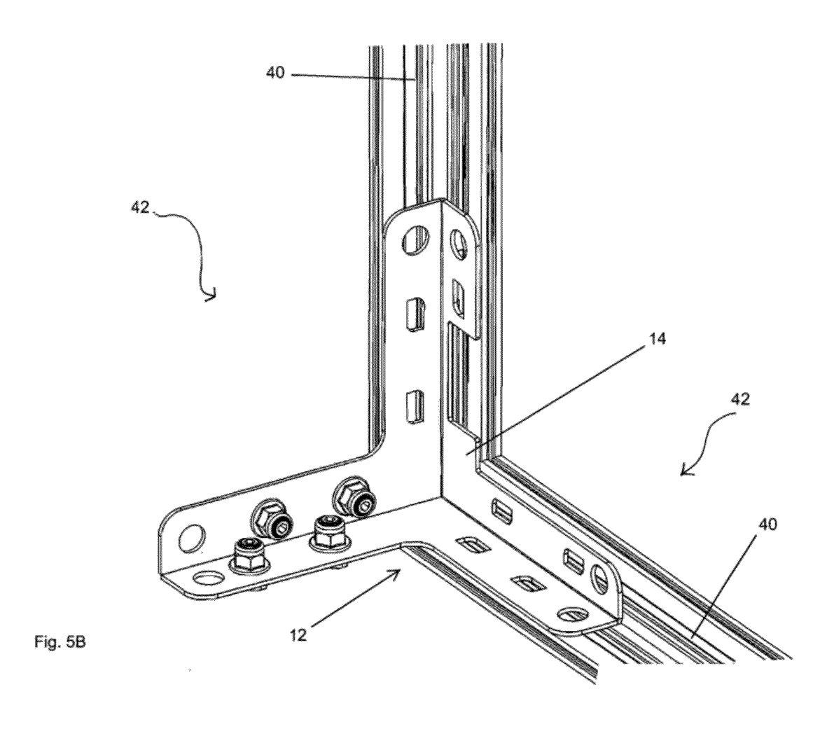

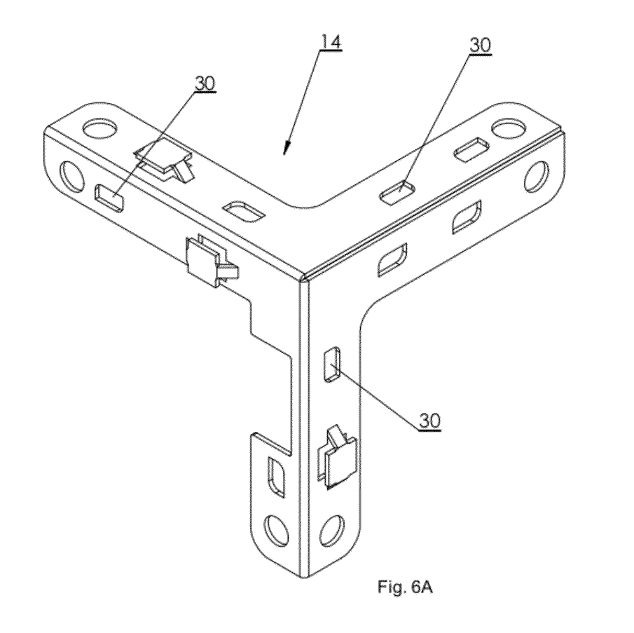

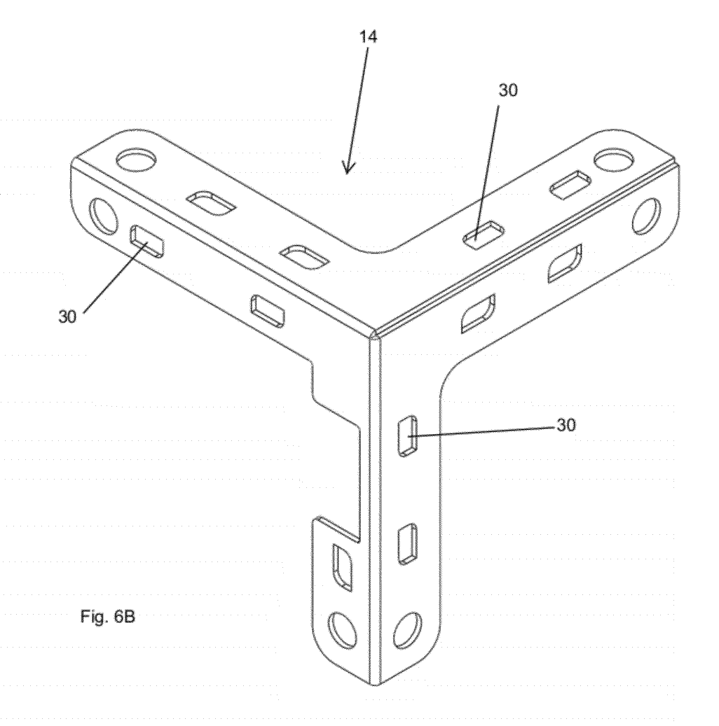

Referring now to FIGS. 5-10, various components are discussed from which frame 12 can be constructed, including elongated frame members, brackets, and fasteners 18. FIG. 5 illustrates an upper corner of frame 12 wherein corner bracket 14 preferably comprises a plurality of holes 30 (see FIG. 6) through which fasteners 18 are secured. Optionally, at least some of holes 30 comprise a non-circular shape such that head 32 of fastener 18 can be inserted through hole 30 and partially rotated such that it locks into place. As best illustrated in FIG. 7, fastener 18 optionally comprises shaped end 34 opposite that of head 32, such that a tool can be used to cause head 32 to rotate once it has been passed through hole 30 of a bracket. In one embodiment, shaped end 34 can comprise a six-sided opening within which an Allen wrench can be inserted and used to rotate head 32 of fastener 18. Of course other shaped ends can be provided and will produce desirable results. However, it is most preferable that shaped end 34 permits a female threaded member, for example nut 36, to pass such that it can be threaded on shaft 38 of fastener 18. As best illustrated in FIG. 5, in one embodiment, lifting point 50 preferably bolts through extruded member 42 and corner bracket 14.

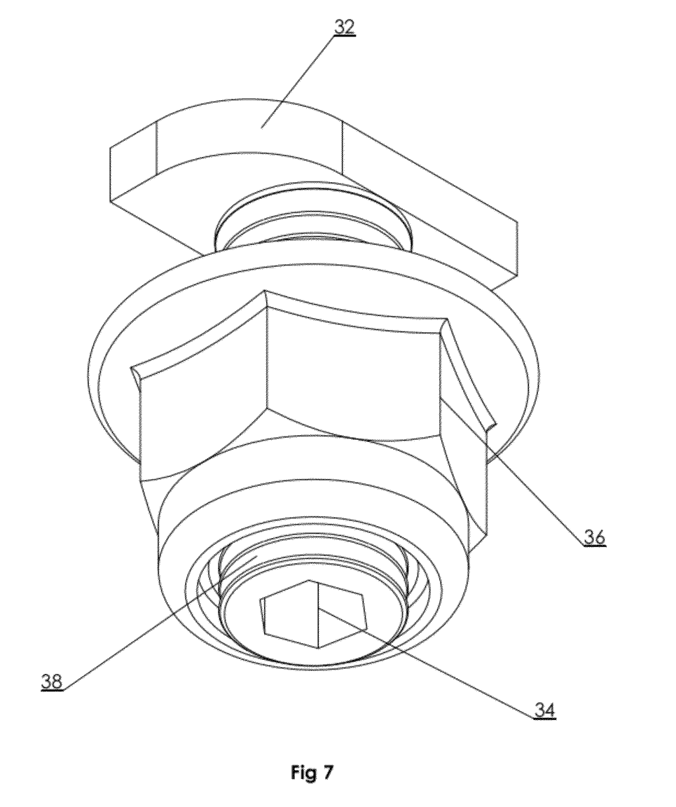

Referring now to FIG. 8, T-bracket 16 is illustrated which is preferably used to connect side frame members to vertical frame members according to an embodiment of the present invention. As with bracket 14, T-bracket 16 also preferably has a plurality of holes 30 disposed in it.

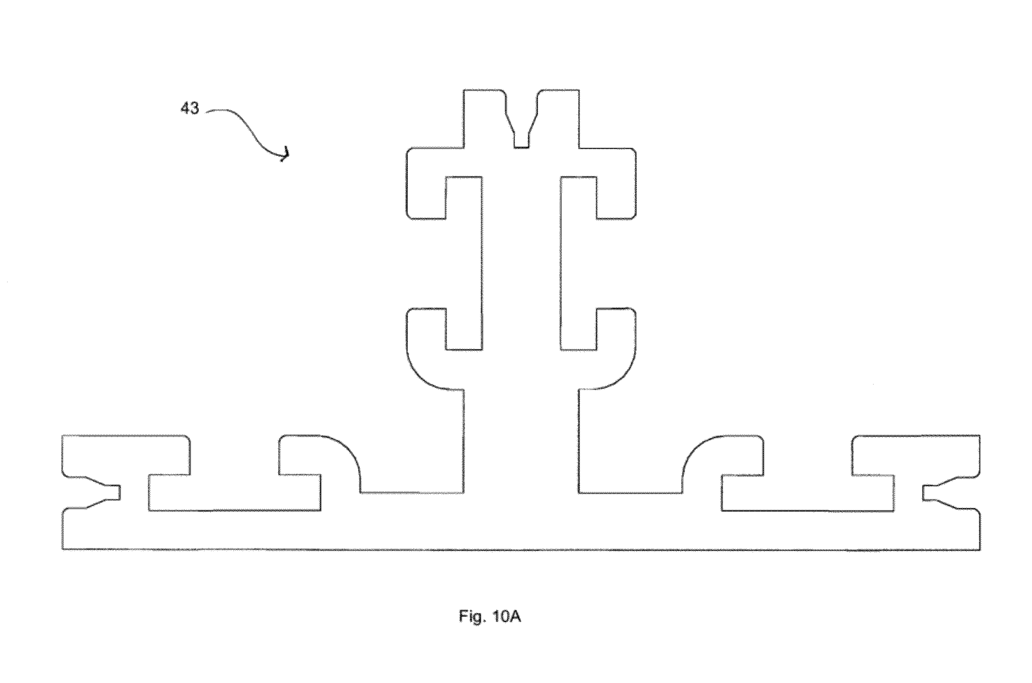

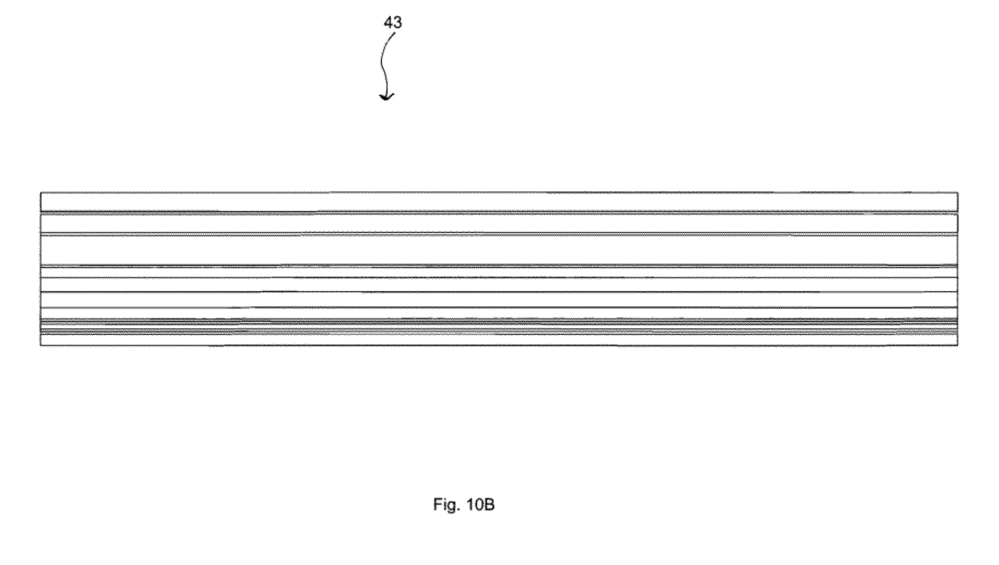

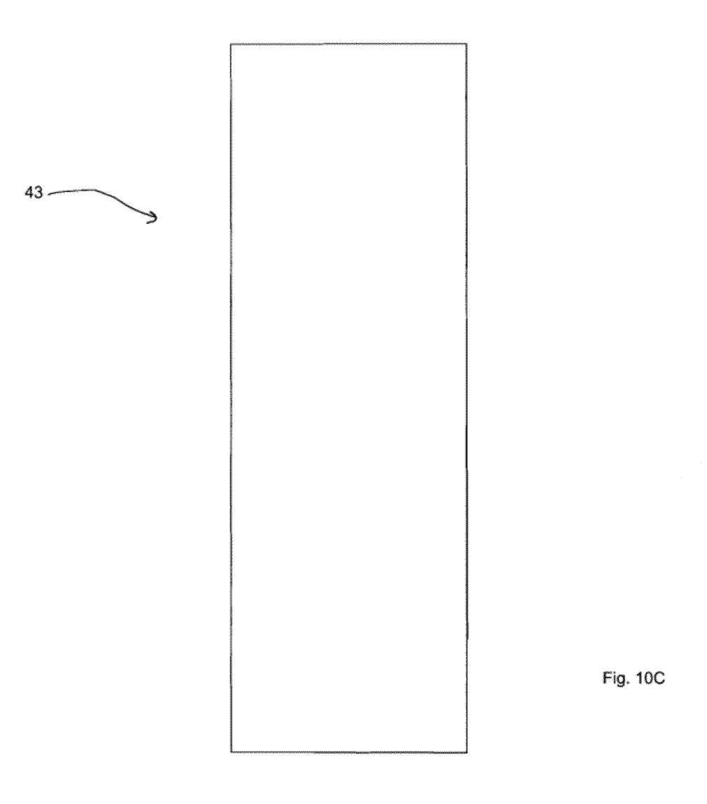

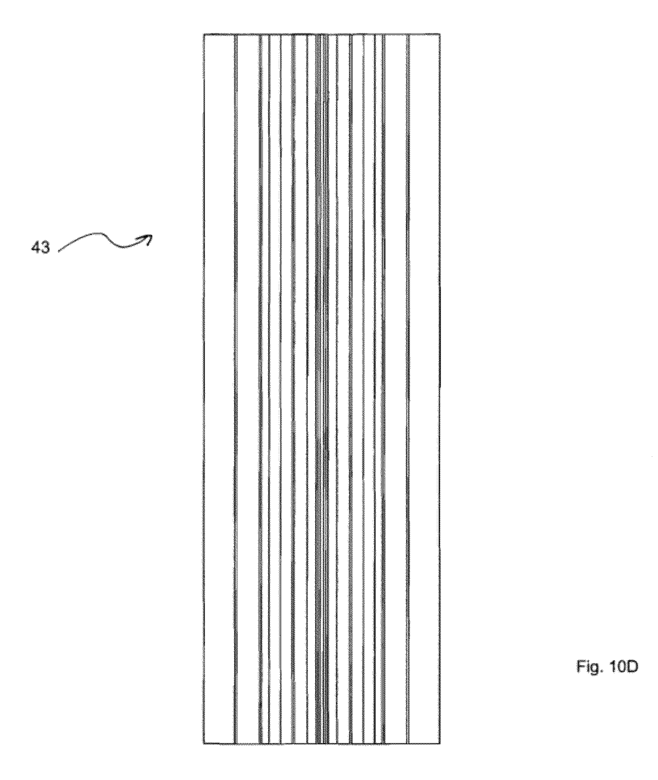

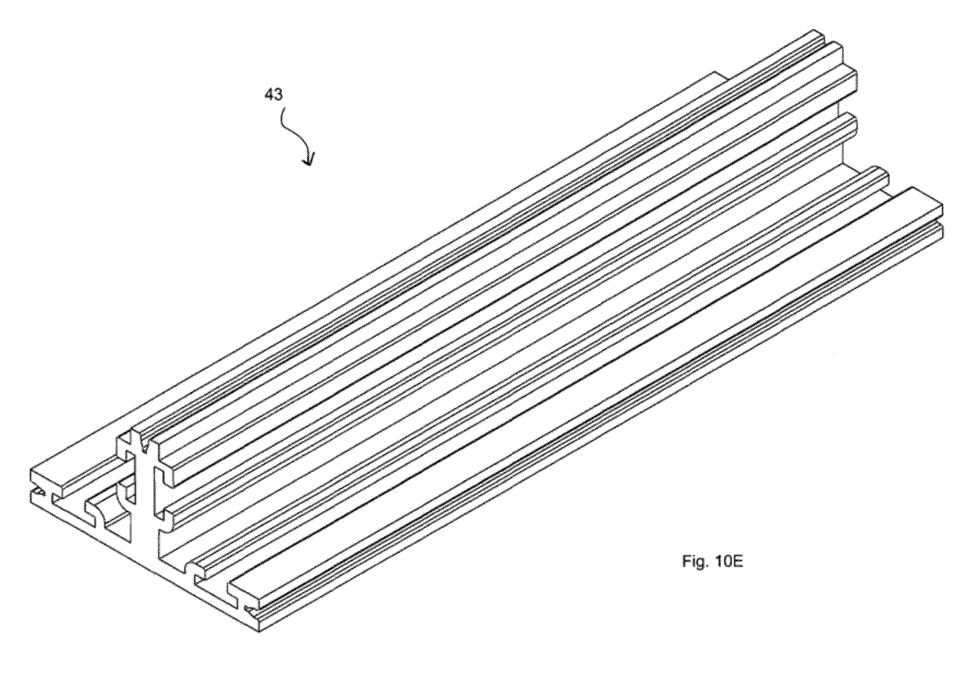

In one embodiment, frame members preferably comprise one or more tracks 40 (see FIGS. 9 and 10) within which head 32 of fastener 18 can be disposed, and tracks 40 are preferably sized such that once head 32 is inserted therein and rotated, head 32 then is trapped within track 40, thereby locking frame members into place with bracket 14 or 16, once nut 36 is screwed onto shaft 38 of fastener 18.

FIGS. 9A and B are perspective-view drawings which illustrate angled elongated frame member 42 with a plurality of tracks 40 disposed therein. Angled elongated frame member 42 is preferably a metal extrusion, most preferably an aluminum-containing metal extrusion. In this embodiment, extruded member 42 is simply cut to length and is preferably use to form the periphery of frame 12 by connecting lengths of frame members 42 together with corner angle brackets. In this embodiment, the cost of manufacturing frame 12 is greatly reduced from stamped and/or cast components which must be individually made to specific dimensions, rather than simply creating long extrusions which are then easily cut to various lengths to create the numerous angled elongated frame members used for frame 12.

In one embodiment, as best illustrated in FIG. 2B, a plurality of cabinets 10 can be combined in a common frame to form multiple unit assembly 11, wherein row of server cabinets 10 are provided such that multiple cabinets are formed into a single unit and can thus be simultaneously moved about and positioned as a single unit. In one embodiment, multiple unit assembly 11 can be formed by providing replacing the right-angle a bracket and/or extrusion that joins two cabinet units together, thus replacing extruded member 42 on each side of cabinet 10 with T-shaped extruded member 43, which is illustrated in FIGS. 10A-E. By forming assembly 11 from T-shaped extruded members 43, rather than simply bolting a plurality of cabinets 10 directly together, one T-extrusion 43 can thus replace two right angle extrusions 42, and one panel 13 can replace the two panels that would otherwise be required by a direct coupling method of individual cabinets 10.

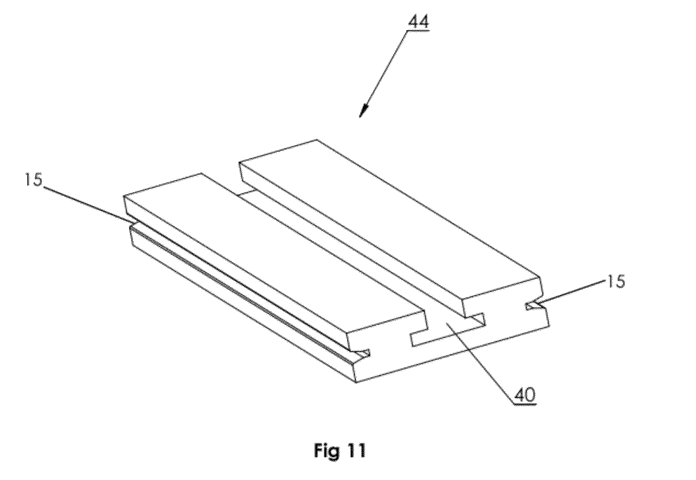

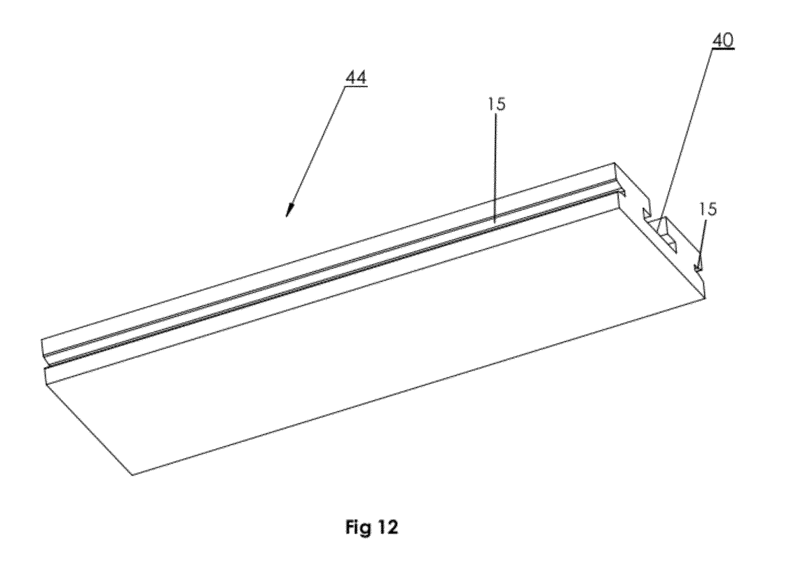

FIGS. 11 and 12 are perspective-view drawings which illustrate flat elongated frame member 44 with track 40 disposed therein. Flat elongated frame member 44 is preferably a metal extrusion, most preferably an aluminum-containing metal extrusion. In this embodiment, extruded member 44 is simply cut to length and is preferably connected to the periphery of frame 12 via T-brackets 16. In this embodiment, the cost of manufacturing frame 12 is greatly reduced from stamped and/or cast components which must be individually made to specific dimensions, rather than simply creating long extrusions which are then easily cut to various lengths to create the numerous flat elongated frame members used for frame 12.

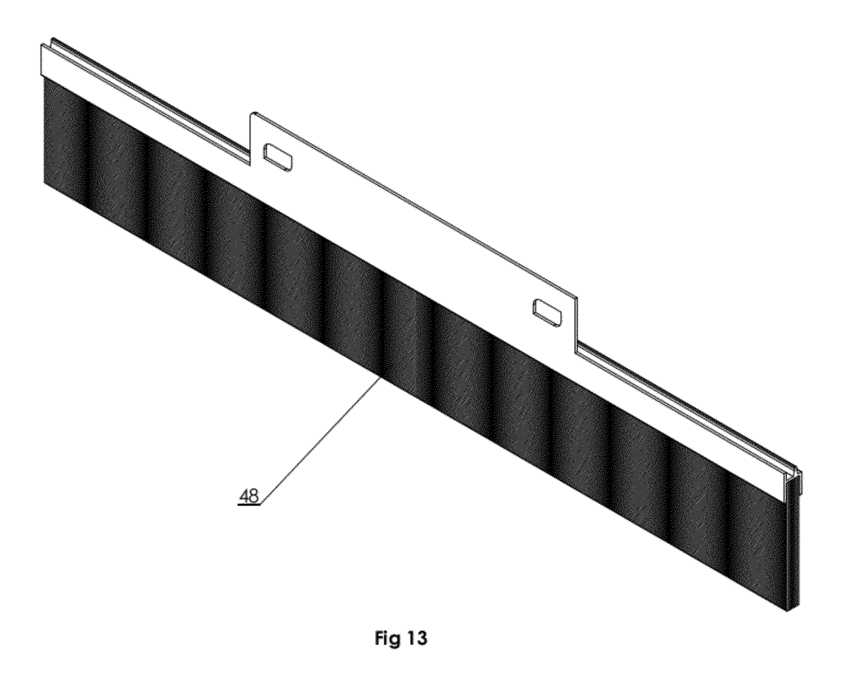

As illustrated in FIG. 1, opening 46 can optionally be provided within cabinet 10. Opening 46 preferably permits cabling and/or airflow into cabinet 10. In one embodiment, one or more brushes 48 (see FIG. 13) can optionally be disposed in opening 46 such that cabling can be passed therethrough while inhibiting contaminants, such as dust, from entering opening 46. Optionally, structures other than brushes can be provided, for example a membrane (e.g., rubber membrane) with a slit in it can be used in place of brush 48 and will also provide desirable results. In one embodiment, brush 48 can optionally be disposed at least partially within a channel of an extruded member.

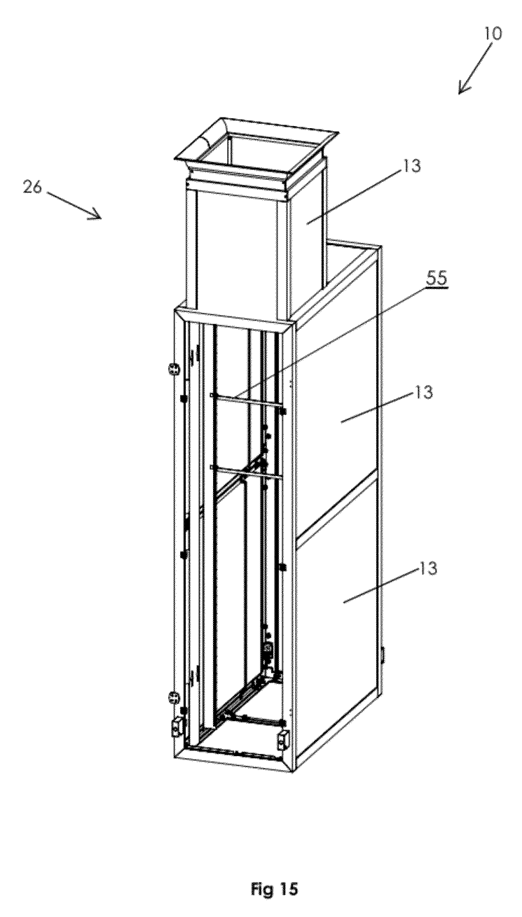

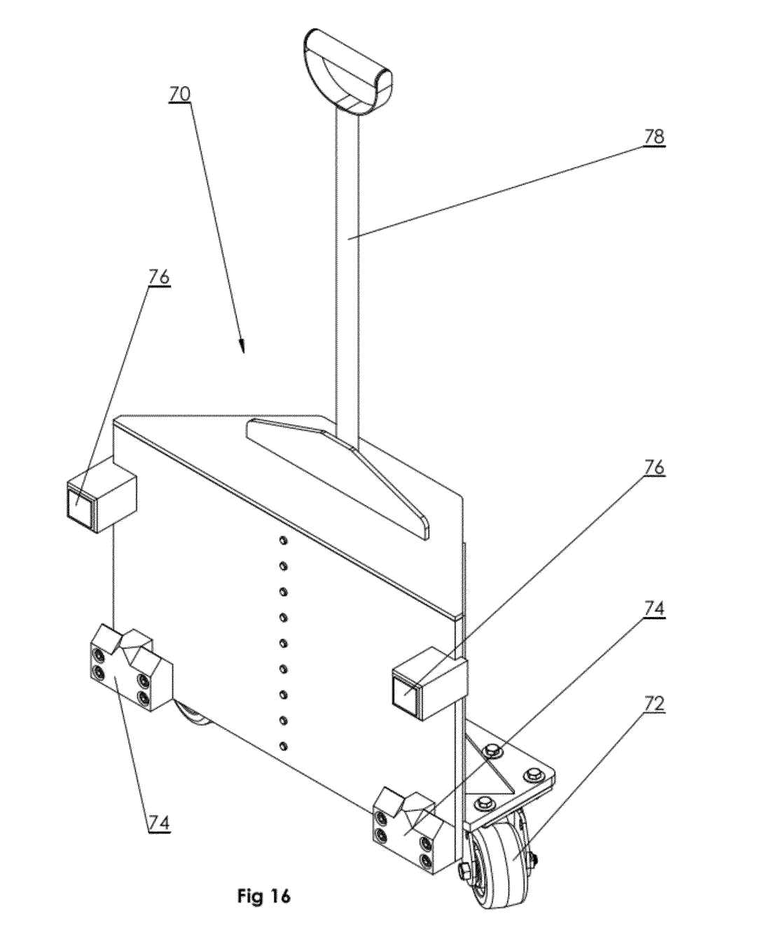

As best illustrated in FIGS. 1-3 and 14A and B, cabinet 10 preferably comprises a plurality of lift points 50 on front and back and/or left and right sides of cabinet 10. Although lift points 50 can of course be configured in various shapes, sizes, and configurations (including but not limited to those illustrated in FIGS. 14A and 14B), in one embodiment, lift points 50 preferably comprise self-aligning member 52, such as a V-shaped notch. Most preferably, lift points 50 are disposed at a lower portion of cabinet 10, near the corners thereof. In one embodiment, self-aligning member 52 of lift points 50 interface with a portion of a lifting mechanism (for example, lifting block 74 of jack 70, see FIG. 18).

FIG. 15 illustrates an embodiment of the present invention wherein cable retention bar 55 is provided, which preferably assists in retaining and routing cables for equipment mounted within cabinet 10.

In one embodiment, cabinet 10 does not comprise any feet or wheels. Accordingly, the entire weight of the cabinet and equipment disposed therein are distributed around the entire base of cabinet 10, this avoiding point-loading created by feet and/or wheels, which often limits the total weight capacity of a cabinet. Thus, in one embodiment of the present invention wherein cabinet comprises a footprint of about 24 inches by about 48 inches, the entire weight of cabinet 10 and the items disposed therein are thus distributed around the entire foot print of about 8 square feet. Further, for embodiments of the present invention which comprise a base of about 24 inches by about 48 inches, because the floor supports for raised floors are often centered on about 24 inch center-to-center spacing, the base of the cabinet can thus rest directly on the floor supports and floor tiles which would normally be placed under the cabinet can therefore be eliminated. In one embodiment, cabinet 10 can have a width of about 24 inches, about 600 millimeters, or any other width that is desired, including but not limited to about 20 feet. In one embodiment, cabinet 10 can have a depth of about 48 inches, about 1200 millimeters, or any other width that is desired. Optionally multiple cabinets of one or more embodiments of the present invention can be placed in rows and each row can be formed from cabinets that each have the same width, or cabinets having more than one width can be placed into rows, for example, a narrow cabinet can be placed between comparatively wider cabinets.

Optionally, in one embodiment, one or more cabinets 10 can be provided with servers, power distribution, and/or data cabling already disposed therein. In one embodiment, one or more jacks 70 can be used to move a fully-loaded cabinet according to an embodiment of the present invention.

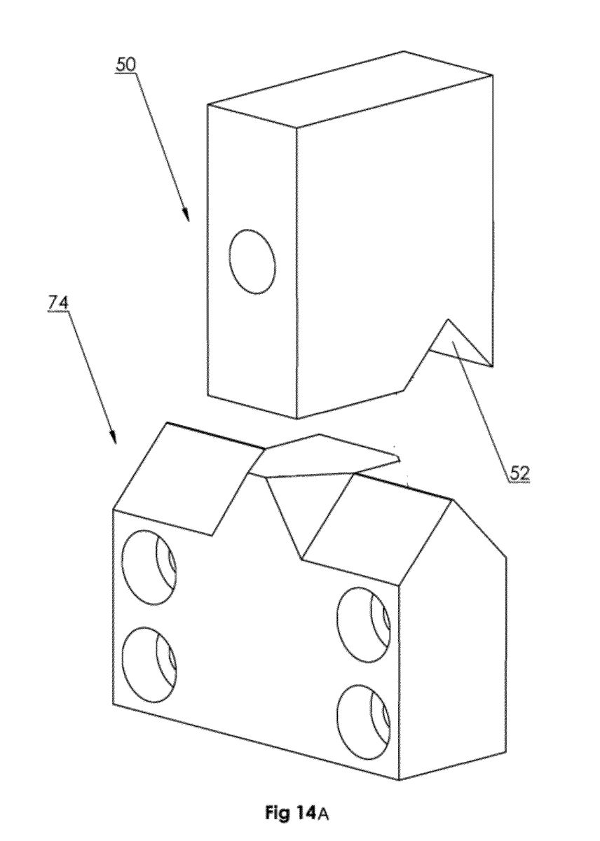

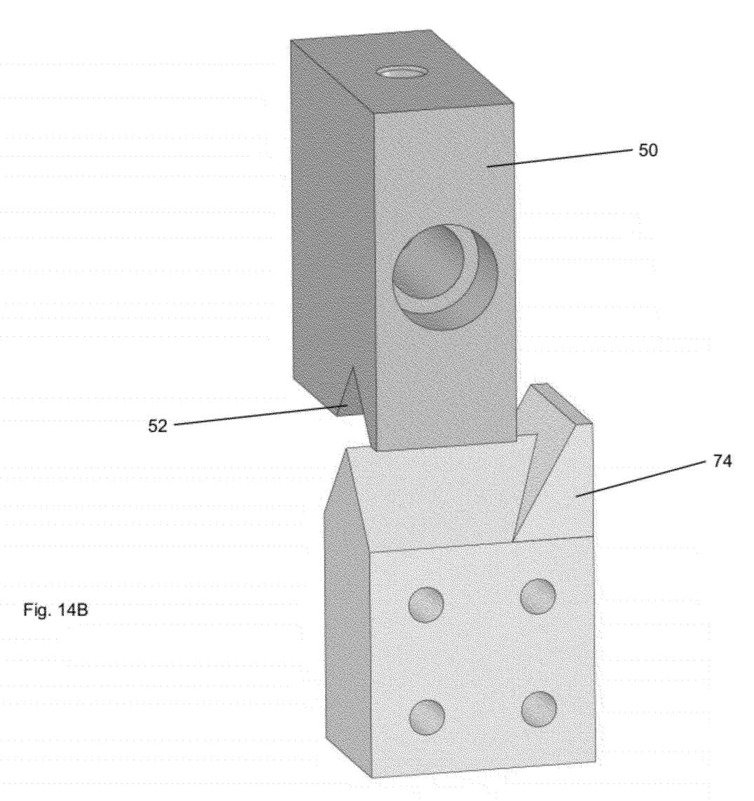

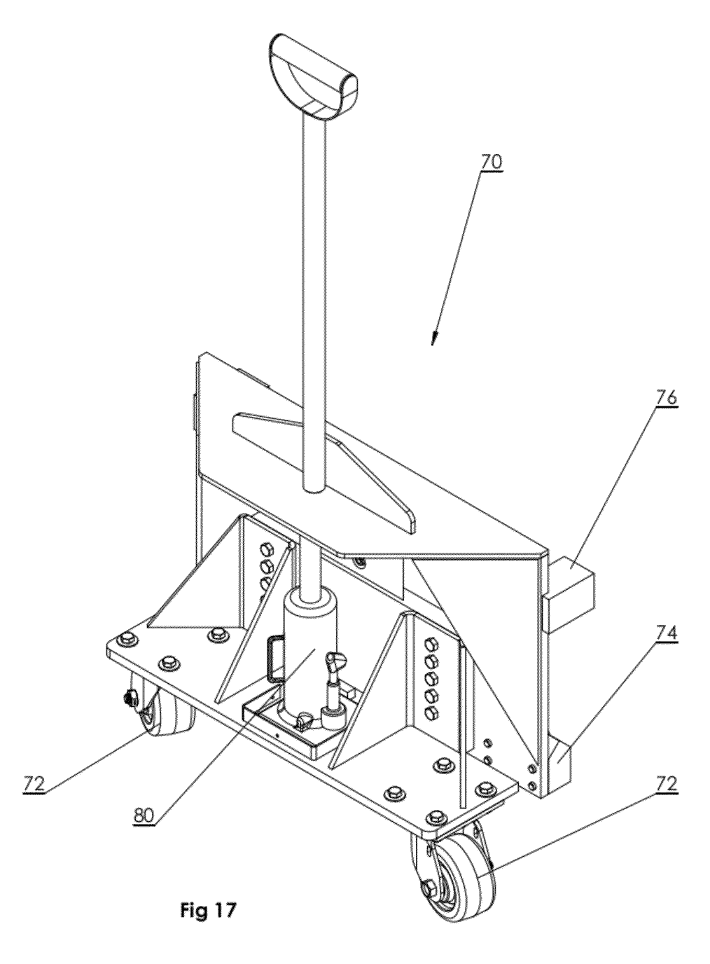

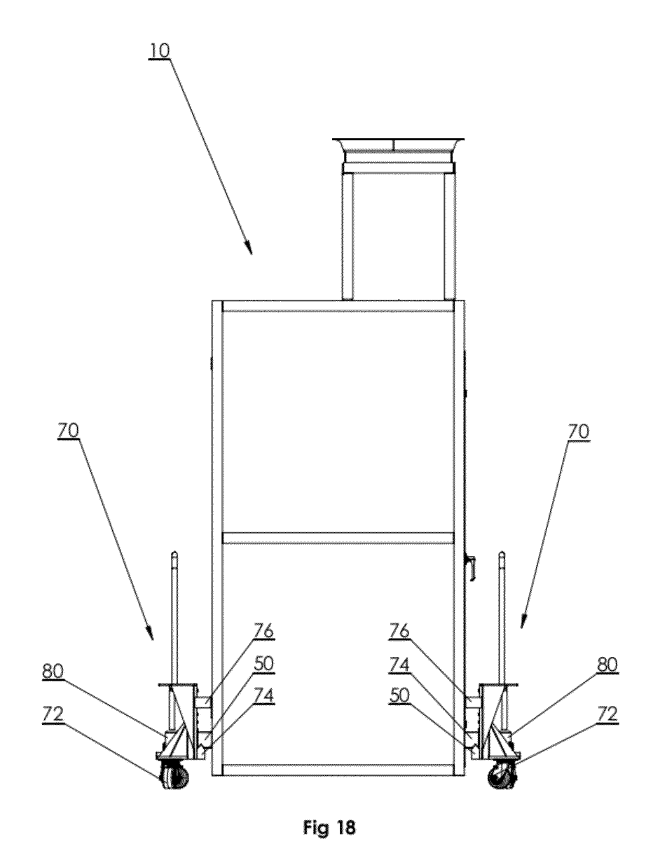

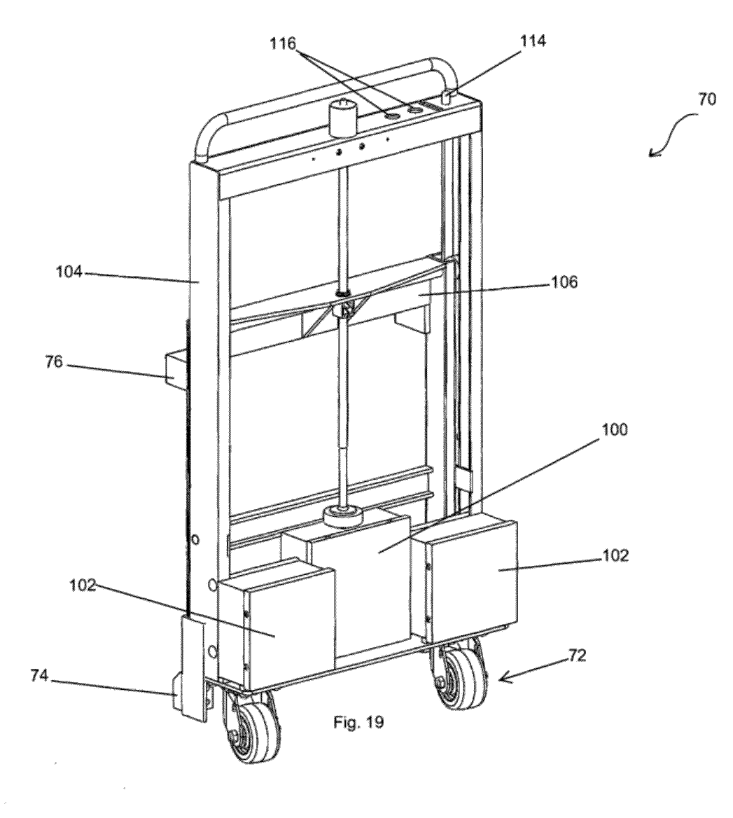

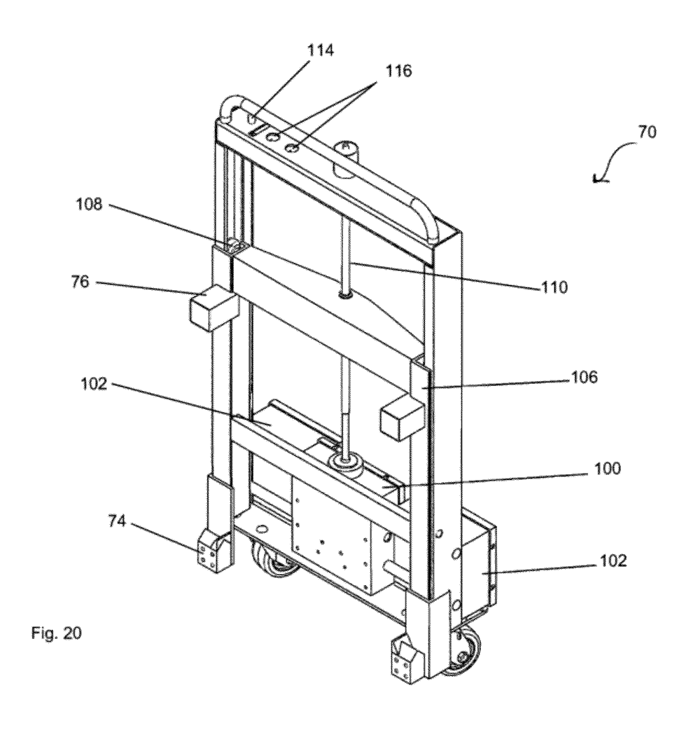

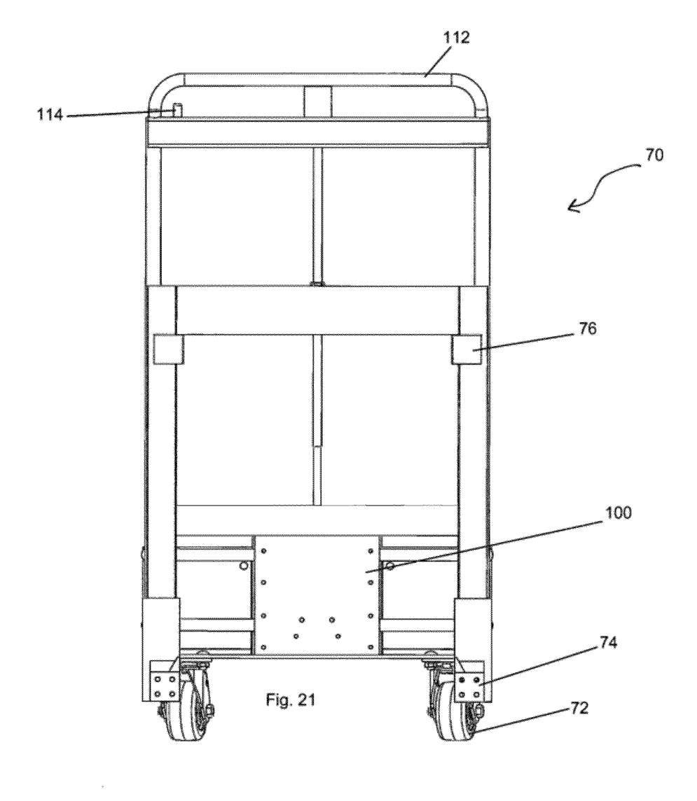

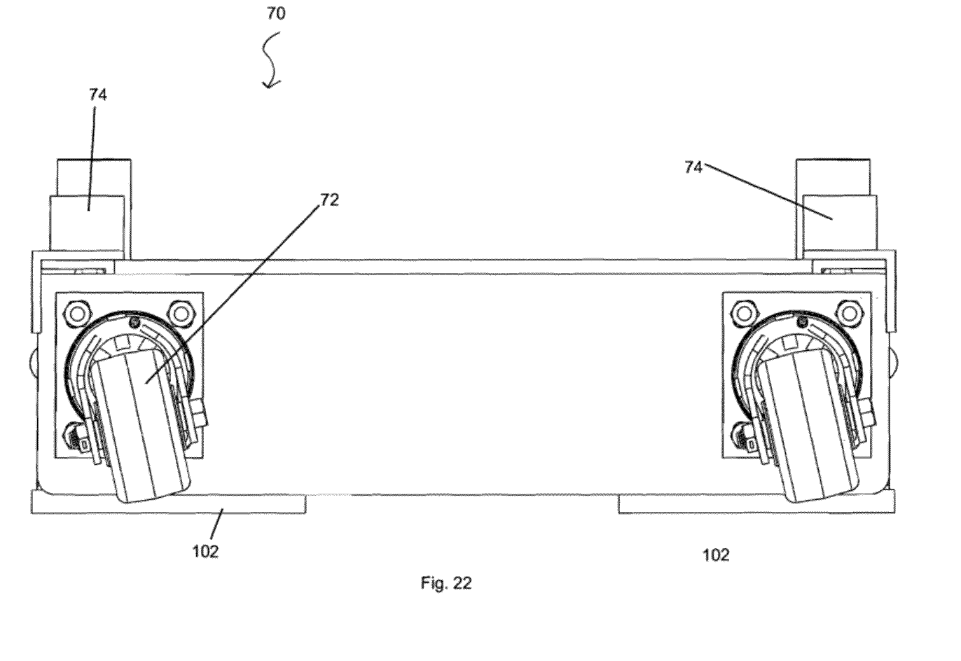

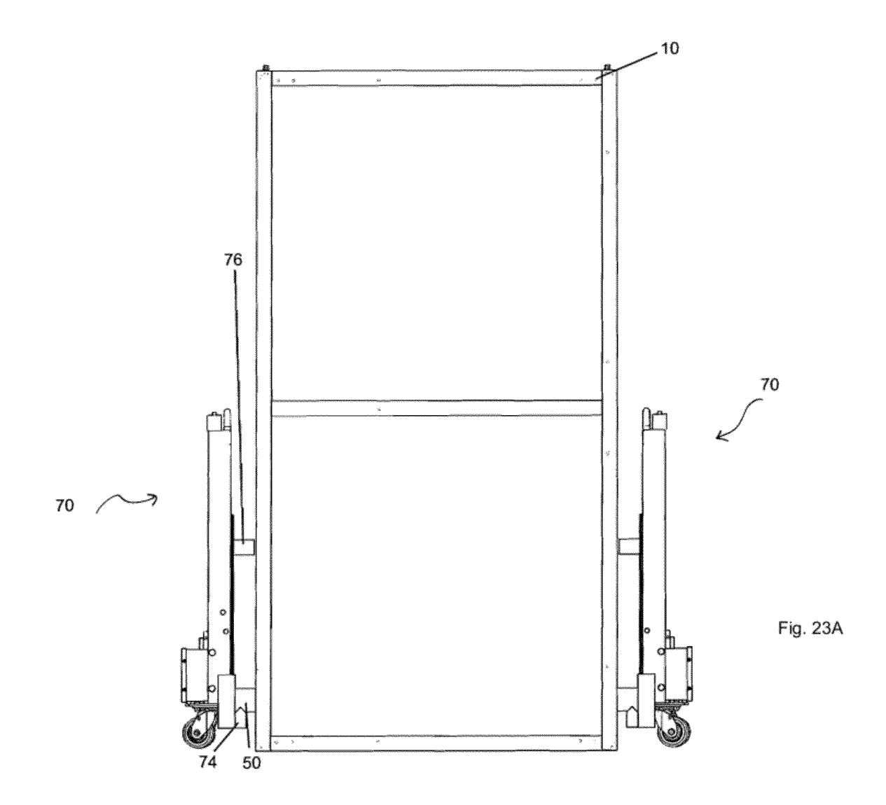

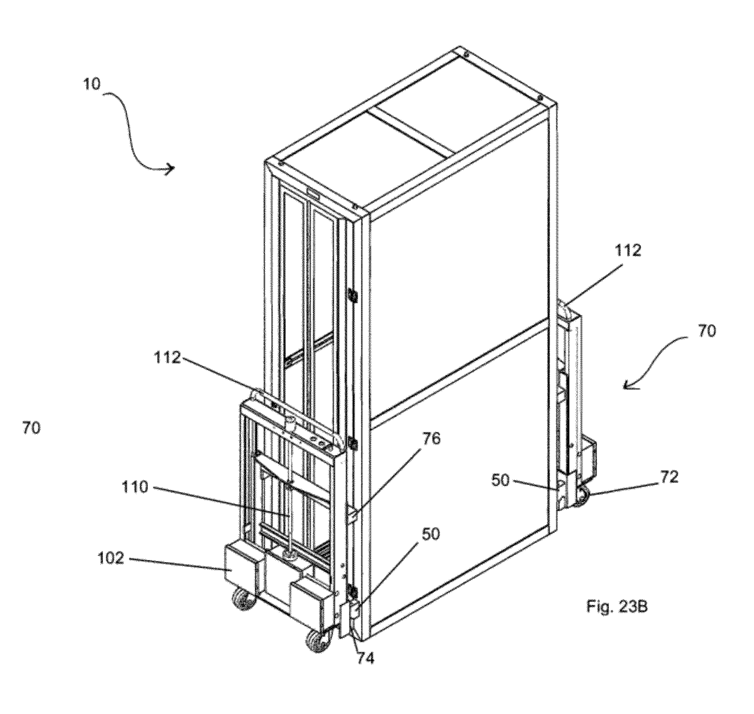

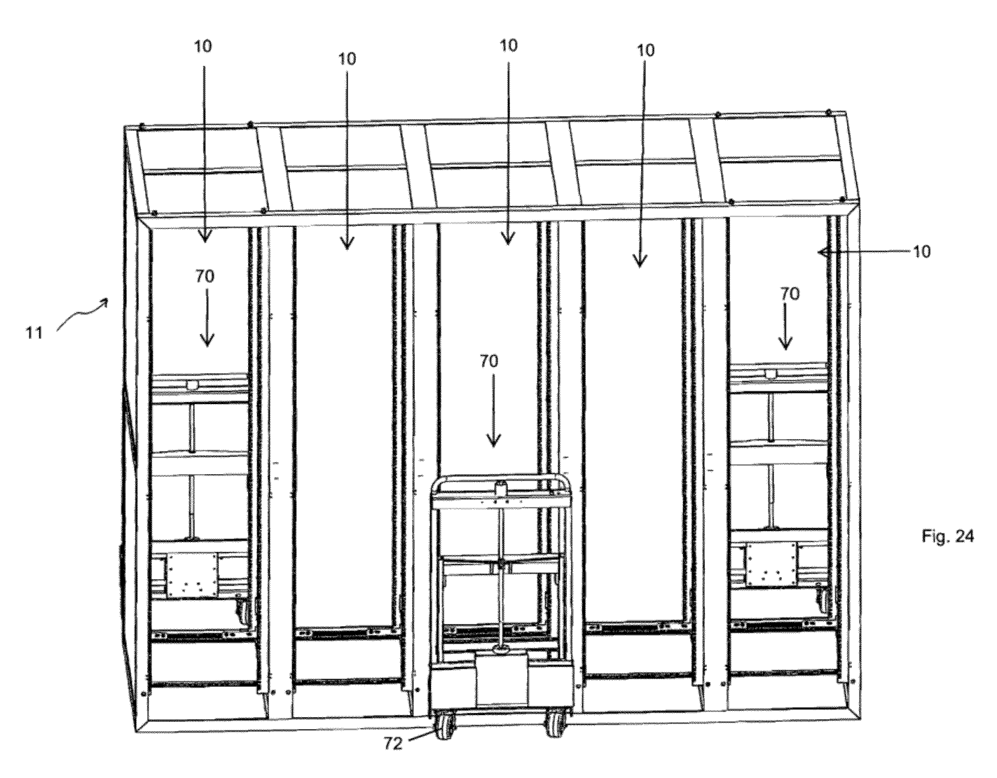

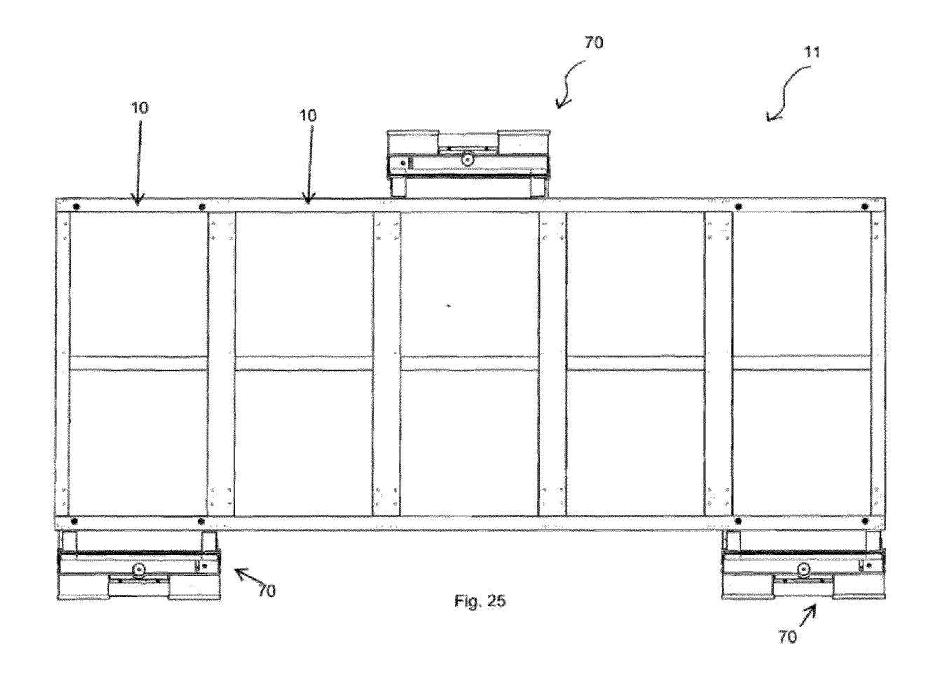

FIGS. 16-26 illustrate embodiments of a lifting jack. In one embodiment, jack 70 preferably comprises a plurality of wheels 72, one or more lifting blocks 74, one or more stop blocks 76, handle 78, and force multiplying mechanism 80. In one embodiment, handle 78 can optionally be coupled to force multiplying mechanism 80, for example in a manner similar to the handle of a common pallet jack. In this embodiment, a pair of jacks 70 are preferably used to lift cabinet 10. As best illustrated in FIG. 18, a first jack is positioned at a front of cabinet 10, and a second jack is positioned at a back of cabinet 10. The jacks are then preferably manipulated such that lifting blocks 74 are caused to engage self-aligning member 52 of lift points 50, thereby lifting cabinet 10 such that its weight is supported by wheels 72. In one embodiment, as best illustrated in FIGS. 19-26, jack 70 can be equipped with powered unit 100 in place of or in combination with force multiplying mechanism 80. In this embodiment, powered unit 100 can include an electrically powered motor, which can optionally be powered from one or more batteries 102, which can be rechargeable batteries. In one embodiment, jack 70 can be configured such that it can have lifting frame 104, which guide movable lifting assembly 106. Optionally, movable lifting assembly 106 can be guided within frame 104 by one or more wheels 108. Of course, other apparatuses, systems, and/or structures can be used in place of wheels 108, including but not limited to rollers, chain and sprockets, guide rails, rods and sleeves, combinations thereof, and the like.

In one embodiment, powered unit 100 can be configured to rotate threaded rod 110 such that lifting assembly 106 can ride up and down threaded rod 110 in response to directional rotation of rod 110. Optionally, however, powered unit 100 can include other configurations for driving lifting assembly 106 up and/or down. For example, unit 100 can lift assembly 106 via a chain and sprocket drive, a hydraulic drive, a pneumatic drive, a gear-drive, a scissor-lift drive, combinations thereof, and the like.

To assist a user in manipulating lifting jack 70, one or more handles 112 can be disposed thereon. Although handle 112 is illustrated as being disposed on a top of jack 70, one or more handles 112 can be placed in one or more places other than or in addition to the top of jack 70.

As best illustrated in FIG. 19, lifting jack 70 can include one or more controls 114 to control the direction and/or speed of the raising and/or lowering of jack 70. (see FIG. 19, 20, 21) In addition, control input/output “I/O” 116 can also be included on lifting jack 70. (FIG. 19, 20, 21—added two jack connections) By providing I/O 116, a plurality of lifting jacks 70 can be linked together in a master/slave relationship, such that when controls 114 of one are manipulated by a user, thus causing that jack to raise and/or lower, the other jacks which are linked thereto via a link through I/O 116 can thus also be caused to raise and/or lower in unison. In this manner, when a plurality of jacks 70 are used to lift one or more items, a user need only manipulate the controls of one of the jacks in order to lift the one or more items equally in unison. Optionally, I/O can be provided via a physical connection, such as a jack and connecting cable, and/or I/O 116 can be achieved via a wireless connection, including but not limited to a radio signal.

Optionally, in one embodiment, one or more of wheels 72 of jack 70 can be made to lock such that they do not swivel. In this manner, when moving an item, one of the wheels can be locked and thus act as an axis of rotation such that jack 70 and the item thereon rotate about the locked wheel. This can provide particularly desirous results when a plurality of jacks are used to lift a large and/or heavy item, including but not limited to a row of joined server cabinets. In this manner, one of the wheels of one of the jacks can be locked and the entire row of cabinets can be pivoted about the locked wheel, such as would be the case when negotiating a tight corner or other sharp turn.

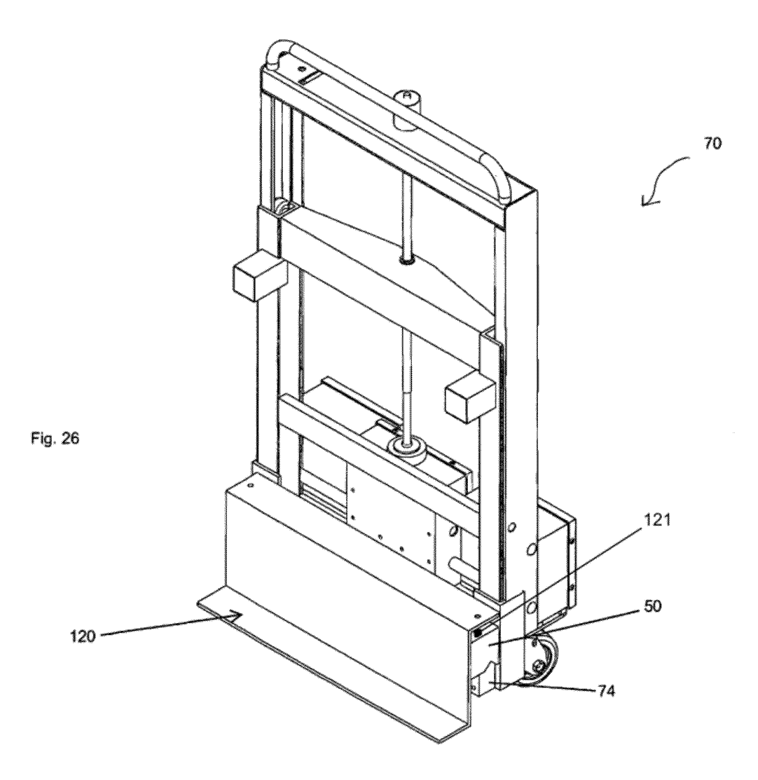

FIG. 26 illustrates an embodiment of the present invention wherein adaptor plate 120 is attached to lifting jack 70. Adaptor plate 120 can be attached to lifting jack 70 such that jack 70 can lift numerous items without requiring that lift points 50 be disposed on them. In one embodiment, lift points 50 are bolted onto jack 70, a hole in the opt of lift point 50 is preferably provided such that adaptor plate 120, which pegs 121 depending downwardly therefrom align with and thus are dropped down into the holes of lift points 50, thus causing adaptor plate 120 to be attached to lifting jack 70. In an alternative embodiment, adaptor plate 120 can be attached to an object to be moved via a secure connection. Jack 70 can then engage lifting points 50 that are attached to adaptor plate 120 such that lifting jack 70 can lift the object to which adaptor plate 120 is attached. Optionally, pegs 121 can be securely attached to and downwardly-depending from adaptor plate 120. Alternatively, however, adaptor plate 120 can be provided with holes through which pegs 121 can be passed through before entering lift points 50, thus forming a removable-pin configuration.

With adaptor plate 120, lifting jack 70 can thus be used to lift other server cabinets and heavy items—not just those of embodiments of the present invention. Adaptor plate 120 thus also provides a fast method of moving electrical switch gear, uninterrupted power sources, cooling units, combinations thereof, and many other heavy loads.

In one embodiment, lifting jack 70 can lift a server or other equipment cabinet, full or empty. In one embodiment, lifting jack 70 can lift and move items having a weight of up to about 2,000 pounds per lifting jack. In one embodiment, multiple lifting jacks 70 can be used to lift a plurality of cabinets or other items which exceed the lifting capacity for a single lifting jack. For example, in one embodiment, several cabinets can be fastened together and filled with equipment, such that the combined weight is about 4,000 pounds per object using two lifting jacks. In this example, lifting jacks can be used to lift and/or move the combined equipment.

In one embodiment, the frame members are not hollow structures. In one embodiment the brackets are not disposed within the ends of the frame members. In one embodiment, the fasteners and frame components comprise a snap-lock fitting. In one embodiment, the frame of the present invention is not held together with conventional hex-head bolts. In one embodiment, at least 50% of the frame of the cabinet of the present invention is constructed from pieces cut from just two extrusions. In one embodiment, at least 75% of the frame of the cabinet of the present invention is constructed from pieces cut from just two extrusions. In one embodiment, at least 85% of the frame of the cabinet of the present invention is constructed from pieces cut from just two extrusions. In one embodiment, at least 90% of the frame of the cabinet of the present invention is constructed from pieces cut from just two extrusions. In one embodiment, at least 95% of the frame of the cabinet of the present invention is constructed from pieces cut from just two extrusions. In one embodiment, 100% of the frame of the cabinet of the present invention is constructed from pieces cut from just two extrusions. In one embodiment, a single cabinet of the present invention can house equipment which uses 10,000 or more watts of power. In one embodiment, a single cabinet of the present invention can house equipment which uses 20,000 or more watts of power. In one embodiment, a single cabinet of the present invention can house equipment which uses 30,000 or more watts of power. In one embodiment, a single cabinet of the present invention can house equipment which uses 35,000 or more watts of power.

In one embodiment, bolts and/or other fasteners pass through corner brackets 14 and frame members 42. In one embodiment, elongated frame components do not meet at corners and attach directly to one another. In one embodiment, frame members 42 and brackets 14 are not slidably connected without one or more fasteners 18. In one embodiment, frame members 42 do not comprise hollow structures. In one embodiment, frame members 42 do not contain a void that is concentrically disposed and surrounded by the material which forms frame members 42. In one embodiment, frame members 42 are not tubes or pipes of square, circular, or other geometric shape. Optionally, server cabinet 10 can comprise any type of rack-mounting cabinet and is thus not limited to only server cabinets.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. A server cabinet comprising:
extruded frame members, said frame members comprising a plurality of groves within which heads of fasteners are slidably disposable; and
corner brackets, said corner brackets comprising a plurality of holes through which the head of a fastener can pass, at least two of said plurality of holes at least substantially aligning with at least one of said plurality of groves of said frame members when at least an end portion of at least two extruded members are positioned onto said corner brackets.

2. The cabinet of claim 1 wherein said extruded frame members comprise a plurality of members that are formed from at least one extruded shape.

3. The cabinet of claim 1 wherein at least some of said plurality holes of said corner brackets comprise a non-circular shape.

4. The cabinet of claim 1 wherein at least some of said plurality of holes of said corner brackets comprise a shape through which a head of a fastener can pass but through which said fastener cannot be removed after a partial rotation of said fastener about a primary axis thereof.

5. The cabinet of claim 1 further comprising at least one T-shaped bracket.

6. The cabinet of claim 1 wherein at least some of said extruded members formed from an aluminum material.

7. The cabinet of claim 1 further comprising a plurality of lift points.

8. The cabinet of claim 7 wherein said lift points comprise a self-aligning portion.

9. The cabinet of claim 8 wherein said self-aligning portion comprises an inverted V-shape

10. The cabinet of claim 7 wherein said lift points are bolted into place through at least one of said frame members and one of said corner brackets.

11. A server cabinet assembly comprising:
a plurality of frame members;
at least one corner bracket;
a plurality of fasteners, said cabinet assemblable by a user by use of said fasteners; and
wherein said frame members and said corner bracket are not disposed in a slidable relationship with one another without fasteners disposed through said corner bracket.

12. The assembly of claim 11 further comprising at least one T-bracket.

13. The assembly of claim 11 wherein said frame members do not comprise elongated hollow structures.

14. The assembly of claim 11 wherein said frame members are not tubular.

15. The assembly of claim 11 wherein said corner brackets do not project into an opening in said frame members.

16. The assembly of claim 11 wherein said frame members do not comprise a hollow interior.

17. A lifting jack comprising:
a plurality of wheels;
a plurality of lifting blocks, said lifting blocks engagable with lift points on an item to be lifted; and
a jack moving handle for moving said jack and a load disposed thereon.

18. The lifting jack of claim 17 further comprising an I/O, said I/O communicating with another lifting jack.

19. The lifting jack of claim 17 further comprising one or more stop blocks.

20. The lifting jack of claim 17 further comprising a lifting frame.

21. The lifting jack of claim 20 further comprising a lifting assembly.

22. The lifting jack of claim 17 further comprising another lifting jack, wherein said lifting jacks are communicably coupled in a master/slave relationship such that when one jack is manipulated the other jack is also manipulated.
